(19) United States
(12) Patent Application Publication
(10) Pub. No.: US 2011/0001472 A1
(43) Pub. Date: Jan. 6, 2011

(54) POSITIONING OF MAGNETIC COILS IN A SENSOR DEVICE

(75) Inventor: Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/808,561

(22) PCT Filed: Dec. 12, 2008
(86) PCT No.: PCT/IB08/55237

§ 371 Date: Jun. 16, 2010

(30) Foreign Application Priority Data
Dec. 20, 2007 (EP) 07123742.4

(51) Int. Cl. G01R 33/12

(52) U.S. Cl. 324/239

(57) ABSTRACT

The invention provides for a method for determining the relative position of at least two magnetic actuator coils (2,3,3′) in a sensor, said coils being arranged on substantially opposite sides of a sensor cartridge (1). By measuring the electromagnetic induction of one of the coils, the relative positions of the coils in the sensor device is determined. Based on the determined relative positions, these positions may be adjusted. Alternatively, the actuation currents in the magnetic coils may be adjusted based on the determined relative positions. Furthermore, a sensor device comprising a sensor cartridge, at least two magnetic coils arranged on substantially opposite sides of the sensor cartridge, and measuring means for determining the electromagnetic induction is provided.

### FIELD OF THE INVENTION

The invention relates to sensor devices comprising at least two magnetic coils arranged above and below a sensor chamber, e.g. a Frustrated Total Internal Reflection (FTIR) biosensor device, and in particular to positioning the magnetic coils.

### BACKGROUND OF THE INVENTION

The demand for biosensors is increasingly growing these days. Usually, biosensors allow for the detection of a given specific molecule within an analyte, wherein the amount or concentration of said target molecule is typically small. For example, the amount of drugs or cardiac markers within saliva or blood may be measured. Drugs-of-abuse are generally small molecules that only possess one epitope and for this reason cannot be detected, e.g., by a sandwich assay. A competitive or inhibition assay is a preferred method to detect these molecules. A well-known competitive assay setup is to couple the target molecules of interest onto a surface, and link antibodies to a detection tag, that may be an enzyme, a fluorophore or magnetic beads. This system is used to perform a competitive assay between the target molecules from the sample and the target molecules on the surface, using the tagged antibodies. For road-side testing, the method to perform the assay, also called assay, should be fast so that a test may be performed in about 1 min, and robust.

In a typical set-up as shown in FIG. 1, at least a portion of a sensor surface 11 of a sensor chamber in a sensor cartridge 1 is prepared for the detection of the target molecules. The sensor chamber in the sensor cartridge 1 should have a predetermined volume. The cartridge 1 may be fabricated as a disposable polystyrene cartridge. Paramagnetic beads 12 are arranged in the sensor chamber, preferably at a predefined location such as at the bottom of the lid of the cartridge 1 as shown in FIG. 1. To increase the reaction speed of target molecules to be detected in a liquid which is inserted into the cartridge 1, magnetic actuation coils 3, 3′ are arranged below the cartridge 1 to generate a magnetic field to pull the beads 12 towards the sensor surface 11. As shown in FIG. 1, generally a pair of coils 3, 3′ is used, being arranged next to each other. However, it is equally possible to only use one magnetic coil below the cartridge 1. After a predetermined time, the lower coils 3, 3′ are switched off and thus the magnetic field is removed, and another magnetic field generated by a magnetic coil 2 arranged above the cartridge 1 may be applied to pull the non-bonded beads 12 away from the sensor surface 11. Subsequently, the presence of beads 12 at binding spots at the sensor surface 11 may be detected. Binding spots are areas at the sensor surface 11 to which the molecules and beads 12 bind in a variety of methods known in the art. One out of several binding methods is the binding of beads 12 to the epitope which in turn binds to an antibody fixed at the binding spots. The amount of epitope within the cartridge 1 can be concluded by detecting the amount of beads bound to the epitope, for example by means of an optical detection method.

Instead of providing an additional upper coil 2 for repelling excessive beads which are not bound, also coils 3, 3′ arranged below the cartridge 1 may be used to locally repel beads 12 from the sensor surface 11, by suitably designing and arranging the lower coils 3, 3′. Furthermore, beads 12 can be repelled from the sensor surface 11 by a combination of the fields of the lower and upper coils arranged above the sensor surface 11 and below the sensor surface 11, respectively, as shown in FIG. 1. Even a single coil having a dedicated geometry may be used to repel beads 12. Removing excessive beads 12 after binding of a part of the beads 12 to the binding spots is also denominated as magnetic washing.

The detection of the beads 12 may be done using for example magneto-resistive techniques. A further known technique is to optically detect the magnetic label beads 12 bound to the binding spots using optical techniques, e.g. FTIR. In a FTIR magnetic biosensor, light 13 emitted from a light source, for example a laser or a LED, is directed onto the sensor surface 11 at an angle of total internal reflection. The course of light is depicted by the black arrows in FIG. 1. If no particles are present close to the sensor surface 11, the light is completely reflected. If, however, beads 12 or other detection tags are bound to the sensor surface 11, the condition of total internal reflection is violated, and a portion of the light is scattered into the sensor chamber or sensor cartridge 1 and thus the amount of light reflected by the sensor surface 11 is decreased. By measuring the intensity of the reflected light with an optical detector, it is possible to estimate the amount of beads 12 bound to the binding spots on the sensor surface 11.

An accurate and reproducible arrangement and positioning of the magnetic coils 2, 3, 3′, in particular an accurate alignment of the coils 2, 3, 3′ present above and below the sensor cartridge 1, is important so that, during a test, the magnetic beads 12 in the sensor cartridge 1 are actuated in an effective and reproducible way. In particular, in case where the chemical bonding is weak, an accurate alignment of the actuation forces generated by the coils is important. In that case, the positioning of the coils 2, 3, 3′ relative to each other is a particularly critical parameter of the measurement.

### SUMMARY OF THE INVENTION

There is therefore a need to provide a method and a sensor device which allows for accurate measurements in a bio sensor.

According to the present invention, electromagnetic induction is used as a position indicator of coils. The method of the invention allows for a determination of the relative position of at least two magnetic actuator coils arranged in a sensor device on substantially opposite sides of a sensor cartridge, for example above and below the sensor cartridge, respectively. The method may make use of the mutual induction between the at least two coils, i.e., the magnetic coupling between these coils. Furthermore, the self-induction of one of the magnetic coils, which depends on the relative position of the coils due to the geometry of the surrounding coils, may be used for determining the relative position of the coils. The dependency of the relative position of the coils from the mutual induction or the self-induction can be determined by an expert in a common way by measuring the electromagnetic induction and the position of the coils and generating a mathematical correlation between these values. Alternatively, the dependency between these values can be determined by forming mathematical equations from common equations of the electromagnetic theory.

The relative position of the coils determined based on the electromagnetic induction may be used to adjust the relative positions of the coils. In case the sensor device includes one magnetic coil above and another magnetic coil below the sensor cartridge, the relative horizontal position of the coils should be adjusted so that the mutual induction between the two coils is maximized in order to achieve an exact alignment of the two coils in line. In order to achieve a symmetric arrangement in a case where more than one coil is arranged on one side of the sensor cartridge, the relative position of the coils should be such that the mutual induction between the upper coil and each one of the lower coils, respectively, are balanced for an optimal positioning. By the term optimal positioning is meant that the coils have the same distance to the binding spots of sensor surface, as shown in FIG. 1, whereby the binding spots are positioned centrally at the sensor surface. The single coil above the sensor surface has to be centrally aligned to the sensor surface for an optimal positioning in this example. Otherwise an accurate measurement of the biosensor is not assured.

Also a vertical adjustment of the distance of the coils may be achieved. By setting the magnetic coupling between the coils to a pre-determined value, the distance between the coils above and below the cartridge may be controlled. Preferably, a vertical positioning is done after the coils are horizontally aligned to adjust for misalignments of the coils.

The positioning of the coils may be further improved by iteratively repeating the steps of measuring the electromagnetic induction, determining and adjusting the relative position of the coils until the measured electromagnetic induction reaches a predetermined value.

The electromagnetic induction measured according to the method of the invention may also be used to adjust the actuation currents, in particular the amplitude of the actuation currents of each coil in order to correct for a displacement of the coils without the need for mechanically re-positioning of the coils.

The mutual electromagnetic induction between coils may be measured by applying a current to one of the coils and observing the induced voltage in the other coils. With the method, also information on the generated magnetic flux, for example on saturation or Eddy currents, may be obtained.

The magnetic coupling may be evaluated in the time domain, for example by supplying pulse-currents to the coils and observe the different responses, as well as in the frequency domain, by looking at varying frequency components.

The invention further provides a sensor device with a sensor chamber in a sensor cartridge and at least two coils arranged on substantially opposite sides of the sensor cartridge. The sensor device further includes measuring means for determining the electromagnetic induction in order to determine the relative positions of the coils. The sensor device may further comprise positioning means for changing the relative position of the coils based on the determined electromagnetic induction. By changing the coil position to the correct alignment measuring faults due to these misalignments are avoided. By applying a soft magnetic material, e.g. a metal or magnetic beads to the sensor (calibration) cartridge, the effect, i.e. the mutual coupling of the magnetic coils, may be enhanced.

With the invention, a method and device for accurately determining the relative position of actuation coils in a sensor device at a low cost is provided, since in a sensor device present actuation coils may be re-used, this means on the one hand used for actuation and repelling of beads in the biosensor and on the other hand used for determining their alignment. The method and device according to the invention provides for robust and reproducible measurements. By adding more than two coils, a better spatial resolution may be realized.

These and other aspects of the invention will be apparent from and elucidated with reference to the embodiments described hereafter.

### BRIEF DESCRIPTION OF THE DRAWINGS

FIG. 1 schematically shows a set-up for a FTIR magnetic biosensor device;

FIG. 2 schematically shows the arrangement of the magnetic coils shown in FIG. 1 with a mutual displacement of the coils; and

FIG. 3 schematically shows a sensor device according to an embodiment of the invention.

### DETAILED DESCRIPTION OF EMBODIMENTS

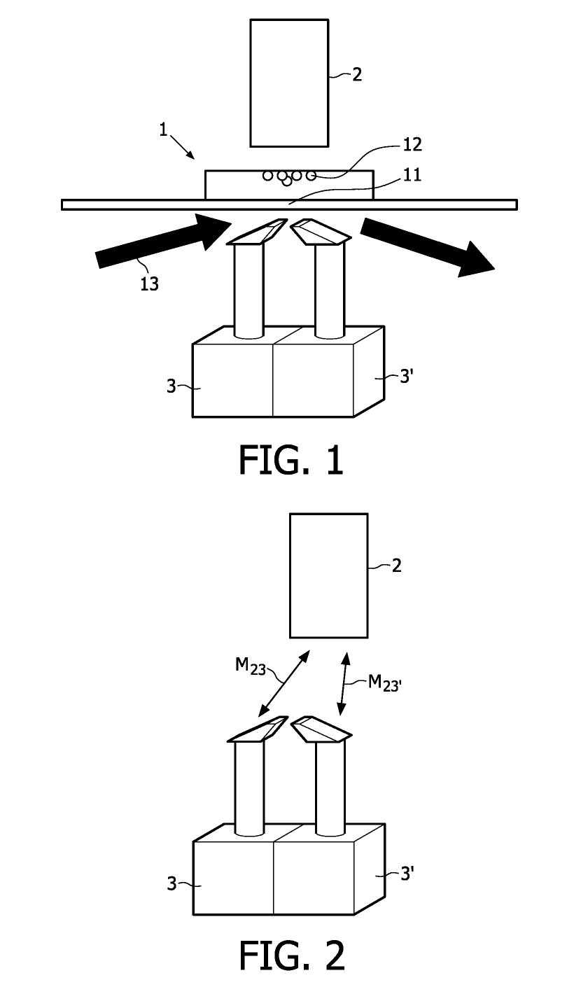

FIG. 2 schematically shows the arrangement of three magnetic coils 2, 3, 3′ used for actuating paramagnetic label beads 12 in a FTIR biosensor device. A sensor cartridge 1 including a sensor chamber and a sensor surface 11, similar to what is shown in FIG. 1, is to be arranged between the top coil 2 and bottom coils 3, 3′. As illustrated in FIG. 2, the top coil 2 is unintentionally displaced, i.e., shifted with respect to the bottom coils 3, 3′ in a horizontal direction.

When in the situation shown in FIG. 2 the magnetic induction of both bottom coils 3 and 3′ is measured by applying a current to the top coil 2 and measuring the voltage induced by the electromagnetic field generated by the current flow in the two bottom coils 3, 3′, a difference in the mutual induction M₂₃ between the top coil 2 and the left bottom coil 3, and the mutual induction M_{23′} between top coil 2 and the right bottom coil 3′ will be observed due to the displacement. By adjusting the relative positions of the coils in a way so that inductions M₂₃ and M_{23′} are equal, a symmetric arrangement of the coils may be achieved which is important for an effective and reproducible actuation of the beads situated in the sensor cartridge 1. Alternatively, the amplitude of the actuation currents in the bottom coils 3, 3′ may be adjusted to correct for the coil displacement and to provide for a substantially homogeneous magnetic field in the sensor cartridge 1.

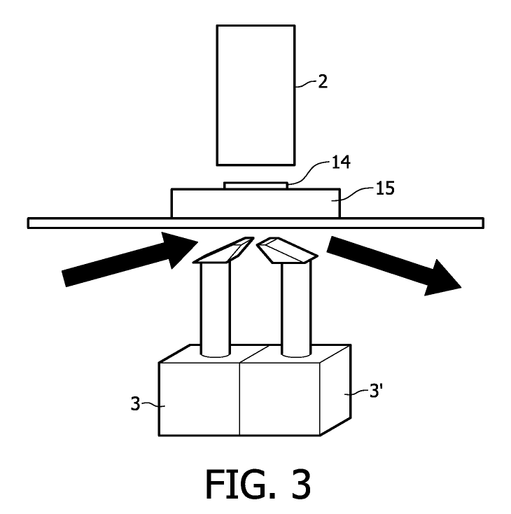

In order to enhance the mutual coupling between the coils, a magnetic material 14 may be arranged on the cartridge 1, 15 as shown in FIG. 3, preferably only during the alignment procedure. A calibration cartridge 15 may be provided which is dedicated to be used during the alignment procedure. The calibration cartridge 15 is replaced by the sensor cartridge 1 after the correct positioning of the coils 2, 3, 3′ is terminated. The magnetic material 14 arranged on the cartridge 1 or calibration cartridge 15 preferably is a soft magnetic material, e.g. a metal or magnetic beads. Such a magnetic material 14 will act as a flux concentrator for the magnetic flux between the upper coils 2 and lower coils 3, 3′ of the sensor device. The flux concentrator enhances the coupling between the upper coils 2 and the lower coils 3, 3′. Furthermore, the flux concentrator makes the coupling between the upper coils 2 and the lower coils 3, 3′ more sensitive to horizontal displacement, thereby improving the determination of the relative position of the coils.

While the invention has been illustrated and described in detail in the drawings and foregoing description, such illustration and description are to be considered illustrative or exemplary and non-restrictive; the invention is thus not limited to the disclosed embodiments. Variations to the disclosed embodiments can be understood and effected by those skilled in the art and practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be considered as limiting the scope.

1. A method for determining the relative position of at least two magnetic coils (2, 3, 3′) of a sensor device, the coils (2, 3, 3′) being arranged on substantially opposite sides of a sensor cartridge (1), the method comprising:
(a) measuring the electromagnetic induction in at least one of the coils (2, 3, 3′); and
(b) determining the relative position of the coils (2, 3, 3′) based on the measured electromagnetic induction.

2. The method according to claim 1, wherein the electromagnetic induction in the at least one of the coils (2, 3, 3′) is measured by applying a current to another one of the coils (2, 3, 3′).

3. The method according to claim 1, further comprising the step of adjusting the relative position of the coils (2, 3, 3′).

4. The method according to claim 3, wherein the relative position of the coils (2, 3, 3′) is adjusted such that the measured electromagnetic induction is maximized in order to align the coils (2, 3, 3′).

5. The method according to claim 3, wherein the relative position of the coils (2, 3, 3′) is adjusted such that the measured electromagnetic induction has a predetermined value in order to control the distance between the coils (2, 3, 3′).

6. The method according to claim 1, wherein the sensor device comprises at least three coils (2, 3, 3′), wherein two of the coils (3, 3′) are arranged on one side of the sensor cartridge (1), wherein the position of the coil (2) arranged on one side of the sensor cartridge (1) relative to the coils (3, 3′) arranged on the other side of the sensor cartridge (1) is determined based on the difference of the electromagnetic induction measured between the coil (2) arranged on one side of the sensor cartridge (1) and each one of the coils (3, 3′) arranged on the other side of the sensor cartridge (1).

7. The method according to claim 6, wherein the relative position of the coils (2, 3, 3′) is adjusted by maximizing the difference of the electromagnetic induction.

8. The method according to claim 3, further comprising iteratively repeating the steps of measuring the electromagnetic induction, determining and adjusting the relative position of the coils (2, 3, 3′) until the measured electromagnetic induction reaches a predetermined value.

9. The method according to claim 1, further comprising the step of adjusting the actuation current of at least one coil to correct for a displacement of the coils (2, 3, 3′).

10. The method according to claim 1, wherein the sensor device is a FTIR magnetic biosensor device.

11. A sensor device comprising:
(a) a sensor cartridge (1);
(b) at least two magnetic coils (2, 3, 3′) arranged on substantially opposite sides of the sensor cartridge (1); and
(c) measuring means for measuring the electromagnetic induction of at least one of the coils (2, 3, 3′).

12. The sensor device according to claim 11, further comprising positioning means for changing the relative position of the coils (2, 3, 3′), wherein the positioning means is adapted to adjust the relative position of the coils (2, 3, 3′) based on the electromagnetic induction measured by the measuring means .

13. The sensor device according to claim 11, wherein the sensor cartridge (1) is a calibration cartridge including a magnetic material, such as a metal or magnetic beads.

14. The sensor device according to claim 11, wherein the device is an FTIR magnetic biosensor device.

15. A calibration cartridge (15) for measuring the alignment of coils (2, 3, 3′) in a biosensor according to claim 11.
